(19) United States
(12) Patent Application Publication
(10) Pub. No.: US 2026/0282514 A1
(43) Pub. Date: Sep. 17, 2026

(54) High Power Super-Heterojunction High Electron Mobility Transistor and Method of Formation

(71) Applicant: The Penn State Research Foundation, University Park, PA (US)

(72) Inventors: Jesse Tyler Kemmerling, University Park, PA (US); Sangwoo Han, University Park, PA (US); Rongming Chu, University Park, PA (US)

(73) Assignee: The Penn State Research Foundation, University Park, PA (US)

(21) Appl. No.: 19/165,912

(22) PCT Filed: Jan. 26, 2024
(86) PCT No.: PCT/US2024/013139

§ 371 Date: Sep. 16, 2025

Related U.S. Application Data
(60) Provisional application No. 63/490,935, filed on Mar. 17, 2023.

(51) Int. Cl. H10D 84/00; H10D 8/60; H10D 30/47; H10D 62/10; H10D 62/824; H10D 64/00

(52) U.S. Cl. CPC H10D 84/101; H10D 30/4735; H10D 30/4738; H10D 30/474; H10D 30/475; H10D 62/107; H10D 62/824; H10D 8/60; H10D 64/111

(57) ABSTRACT

Embodiments relate to a super-heterojunction high electron mobility transistor structure. A n-type modulation doping with barrier layer induces a two-dimensional electron gas (2DEG) channel and allows for charge balancing to reduce peak electric fields at a drain-side of a gat contact to increase breakdown voltage. The n-type modulation doped layer is adjacent to at least one p-type layer to generate a charge balanced super-heterojunction region. A p-ohmic contact ensures that the processes of depleting and accumulating of electrons and holes in the structure are fast enough for practical switching operation. The structure can be expanded to a plurality of 2DEG channels. The gate and p-ohmic contact design (with utilization of spin-on-glass or other protective layer) may provide for larger breakdown voltage and mitigation of current collapse effect into the kilovolt range and beyond.

### CROSS-REFERENCE TO RELATED APPLICATIONS

This patent application is related to and claims the benefit of priority to U.S. provisional patent application No. 63/490,935, filed on Mar. 17, 2023, the entire contents of which is incorporated by reference.

### STATEMENT REGARDING FEDERALLY SPONSORED RESEARCH OR DEVELOPMENT

This invention was made with government support under Grant No. N00014-21-1-2193 awarded by the United States Navy/ONR and under Grant No. DE-AR0001478 awarded by the Department of Energy (ARPA-E). The Government has certain rights in the invention.

### FIELD OF THE INVENTION

Embodiments relate to a super-heterojunction GaN/AlGaN/GaN structure that allows for charge balancing to reduce peak electric fields at a drain-side of a gate contact to increase breakdown voltage, and further ensures that the processes of depleting and accumulating electrons and holes in the structure are fast enough for practical power switching applications.

### BACKGROUND OF THE INVENTION

A lateral gallium nitride (GaN) field effect transistor (FET), typically in the form of a high electron mobility transistor (HEMT), has been demonstrated with breakdown voltage (BV) below and into the kilovolt range, and upwards of 10 kV. However, reported dynamic switching of GaN FETs was only up to 1 kV off-state bias. This may be partly because, for GaN-on-Si HEMT, the BV is limited to around 1 kV by the thickness of GaN achievable on Si substrate. This may also be because, although surface/buffer trapping depletes the 2D electron gas (2DEG) between the gate and the drain leading to linear increase of BV with increasing gate-to-drain spacing, surface/buffer trapping may cause severe degradation of dynamic on-resistance, making the device impractical to function as a switch.

### SUMMARY OF THE INVENTION

Disclosed are embodiments of a super-heterojunction structure. The super-heterojunction structure may include a p-ohmic layer. The p-ohmic layer may be electrically grounded to a source electrode. The source electrode may be electrically grounded to at least one two-dimensional electron gas (2DEG) channel.

The at least one 2DEG channel may include at least one n-type modulation doped layer and at least one p-type layer.

The p-ohmic layer may include a p-ohmic contact metal.

The n-type modulation doped layer may be formed by any one or combination of n-type barrier layer doping, n-type 8-doping in the barrier layer, n-type doping at an interface between the barrier layer and the at least one p-type layer, and/or n-type 8-doping at an interface between the barrier layer and the at least one p-type layer.

The n-type modulation doped layer may be adjacent to the p-type layer to generate a charge balanced super-heterojunction region. The at least one p-type layer may include at least two p-type layers. A first p-type layer may include GaN and a second p-type layer may include AlGaN.

The super-heterojunction structure may include a p-type dopant for the p-type layer. The p-type dopant for the p-type layer may include any one or a combination of Mg, Li, Na, K, Be, Zn Ca, and Be.

The super-heterojunction structure may further include at least one second 2DEG channel.

The super-heterojunction structure may include a plurality of 2DEG channels of claim 1.

Disclosed are embodiments of a transistor. The transistor may include at least one diode having the super-heterojunction structure as described herein.

Disclosed are embodiments of a transistor including the super-heterojunction structure of as described herein.

Disclosed are embodiments of a transistor including a super-heterojunction structure having at least one two-dimensional electron gas (2DEG) channel and a p-ohmic layer.

The at least one 2DEG channel may include a n-type modulation doped layer and at least one p-type layer. The n-type modulation doped layer may be adjacent to the at least one p-type layer to generate a charge balanced super-heterojunction region. The transistor may further include a drain contact and a p-ohmic contact.

The drain electrode may be configured as a n-ohmic contact and the p-ohmic contact may be configured as a p-ohmic layer.

The n-ohmic contact may form a n-ohmic contact between the drain electrode and the at least one 2DEG channel.

The p-ohmic contact may form an ohmic contact with at least one p-type layer.

The transistor may include a p+ layer that may be formed between the p-ohmic contact and the at least one p-type layer.

The transistor may include a n-ohmic source contact. The n-ohmic source contact and the p-ohmic layer may be electrically connected.

The transistor may include a source contact that may be configured as a n-ohmic contact.

The drain contact and the source contact may form an ohmic contact with the at least one 2DEG channel.

The transistor may include a notch configured to reduce or eliminate hole conduction between the source contact and the drain contact, and between the p-ohmic contact and the drain contact.

The notch may be a void formed by etching or a region formed by plasma treatment. The transistor may include a plurality of 2DEG channels.

The transistor may further include a p-n junction comprising a p-type region and a n-type region. The source contact may be in electrical connection with the p-type region. The source contact may be in electrical connection with the n-type region. The drain contact may be in electrical connection with the n-type region.

Disclosed are embodiments of a transistor including a super-heterojunction structure. The super-heterojunction structure may include a p-ohmic contact and a charge balance region. The charge balance region may include a passivation layer, a p-type layer adjacent to the passivation layer, an unintentionally doped (UID) spacer layer adjacent to the p-type layer, an UID barrier layer adjacent to the UID spacer layer, a n-type modulation doped layer between the UID spacer layer and the UID barrier layer, an UID channel layer adjacent to the UID barrier layer, and a buffer layer adjacent to the UID channel layer. The transistor may further include a drain contact and a source contact.

The source contact may be configured as a n-ohmic contact formed with the at least one 2DEG channel and may be electrically connected to a p-ohmic contact.

The n-ohmic contact forms a n-ohmic contact between the drain contact and the at least one 2DEG channel.

The p-ohmic contact may form an ohmic contact between a p-ohmic metal and the at least one p-type layer.

The transistor may include a p+ layer formed between a p-ohmic metal and the at least one p-type layer.

The drain contact and the p-ohmic contact may be electrically connected.

The n-ohmic contact may form an ohmic contact between the source contact and at least one 2DEG channel.

The transistor may include a plurality of 2DEG channels.

The transistor may further include a p-n junction including a p-type region and a n-type region. The source contact may be in electrical connection with the p-type region. The source contact may be in electrical connection with the n-type region. The drain contact may be in electrical connection with the n-type region.

The p-ohmic layer may include a Ni layer, a Au layer, a Pd layer, a PT layer, or any combination thereof.

Disclosed are embodiments of a super-heterojunction structure including spin-on-glass (SiO2) or other protective layer utilized as a protective barrier to protect the p-ohmic contact and p-type layer. The SiO2 may be further utilized as an insulating barrier under a metal.

Disclosed are embodiments of a super-heterojunction structure including a p-ohmic contact designed to only contact the p+ layer.

The p-ohmic contact may be electrically shorted with a source contact.

The p-ohmic contact may be electrically isolated from a gate contact.

The gate contact may have a symmetric or asymmetric structure.

The gate contact design may reduce trapping between the gate contact and the p-ohmic contact.

The super-heterojunction structure may further include a continuous gate trench sidewall on the p-ohmic contact side of a gate trench of the gate contact.

The spin-on-glass (SiO-2) or other protective layer may function as a self-aligned mask for a continuous gate-trench side-wall.

The super-heterojunction structure may include a termination of the p-ohmic contact at an edge of a transistor isolation side-wall for electric-field termination.

The super-heterojunction structure may include a termination of the p-ohmic contact where the p-ohmic contact overhangs an edge of a transistor isolation side-wall for electric-field termination.

The termination of the p-ohmic contact may include an extension of a device active region outside a rectangular isolation sidewall.

The termination of the p-ohmic contact may include no extension of a device active region outside a rectangular isolation sidewall.

The termination of the p-ohmic contact may include a p+-type layer unetched at a transistor isolation side-wall.

The termination of the p-ohmic contact may include a p+-type layer etched at a transistor isolation side-wall.

The super-heterojunction structure may include a metal connection between the source contact and the p-ohmic contact. The metal connection may be within a surface area of the p-ohmic contact and the p+-type layer.

The super-heterojunction structure of claim 35, wherein a metal connection between the source contact and the p-ohmic contact is outside a surface area of the p-ohmic contact and the p+-type layer.

The super-heterojunction structure may further include an etch opening of the spin-on-glass (SiO2) or other protective layer and an etch opening of a gate dielectric layer for a connection of metal to the p-ohmic contact. The connection of metal may be limited to within a surface area of the p-ohmic contact and the p+-type layer.

### BRIEF DESCRIPTION OF THE DRAWINGS

The above and other objects, aspects, features, advantages and possible applications of the present invention will be more apparent from the following more particular description thereof, presented in conjunction with the following drawings, in which:

FIG. 1 shows an exemplary cross section view of a structure of a super-heterojunction (SHJ) high electron mobility transistor (HEMT).

FIGS. 2A and 2B show exemplary cross section views of a structure of a SHJ field effect transistor (FET) having a single channel and a double channel, respectively. The gate shown in FIG. 2B is an asymmetric gate.

FIG. 2C shows an exemplary cross section view of a symmetric gate that may be used in a structure of a SHJ FET such as embodiments as described herein.

FIG. 2D shows a microscopic image of a SHJ metal oxide silicon field effect transistor (MOSFET).

FIGS. 3A and 3B show current-voltage (I-V) plots for various lengths of a double channel SHJ structure. FIG. 3A shows transfer I-V for a double channel SHJ-MOSFET and FIG. 3B shows output I-V for double channel SHJ-MOSFET.

FIGS. 4A and 4B show current-voltage (I-V) plots for a single channel SHJ structure contrasted with various lengths of a double channel SHJ structure. FIG. 4A shows transfer I-V for a single channel SHJ-FET and various lengths of a double channel SHJ-MOSFET. FIG. 4B shows output I-V for a single channel SHJ-FET and a double channel SHJ-MOSFET.

FIGS. 5A and 5B show various measurement configurations for performing dynamic switching measurements and measuring various properties of a SHJ structure as disclosed herein. FIG. 5A shows a measurement configuration for dynamic switching measurements using a Keysight N1267A fast switch and a Keysight high current SMU, medium current SMU, high voltage SMU, and ground unit to control the source and the drain. FIG. 5B shows an off-state stress measurement configuration, where a 10 kV power supply (Keithley 2290-10) may provide a drain bias, and a Keithley 2363B dual channel SMU may provide the source and gate bias while measuring the source leakage current Is.

FIGS. 6A, 6B, 6C, and 6D show various measurement results generated from performing dynamic switching measurements using various measurement configurations. FIG. 6A shows a breakdown voltage (BV) I-V comparison between a measurement configuration using the Keysight measurement configuration as shown in FIG. 5A and a measurement configuration using the Keithley measurement configuration as shown in FIG. 5B. FIG. 6B shows BV I-V measurement results for various lengths of a SHJ structure using the Keithley measurement configuration as shown in FIG. 5B. FIG. 6C shows results of a dynamic switching measurement for various lengths of a SHJ structure. FIG. 6D shows results of a dynamic switching measurement for a single channel SHJ-FET, a single channel SHJ-SBD, and various lengths of double channel SHJ-MOSFETs.

FIG. 7 shows a plot of various waveforms of dynamic switching measurements of a SHJ-MOSFET. For example, as shown in FIG. 7, waveforms corresponding to parameters such as gate voltage, drain voltage, drain current, and/or gate current may be shown over time.

FIGS. 8A and 8B show plots relating to benchmarking SHJ-MOSFETS versus GaN transistors for parameters such as blocking voltage, dynamic switching, and dynamic drain-to-source on-resistance (R_{DS(ON)}) and dynamic/static R_{DS(ON)}.

### DETAILED DESCRIPTION OF THE INVENTION

The following description is of exemplary embodiments that are presently contemplated for carrying out the present invention. This description is not to be taken in a limiting sense, but is made merely for the purpose of describing the general principles and features of the present invention. The scope of the present invention is not limited by this description.

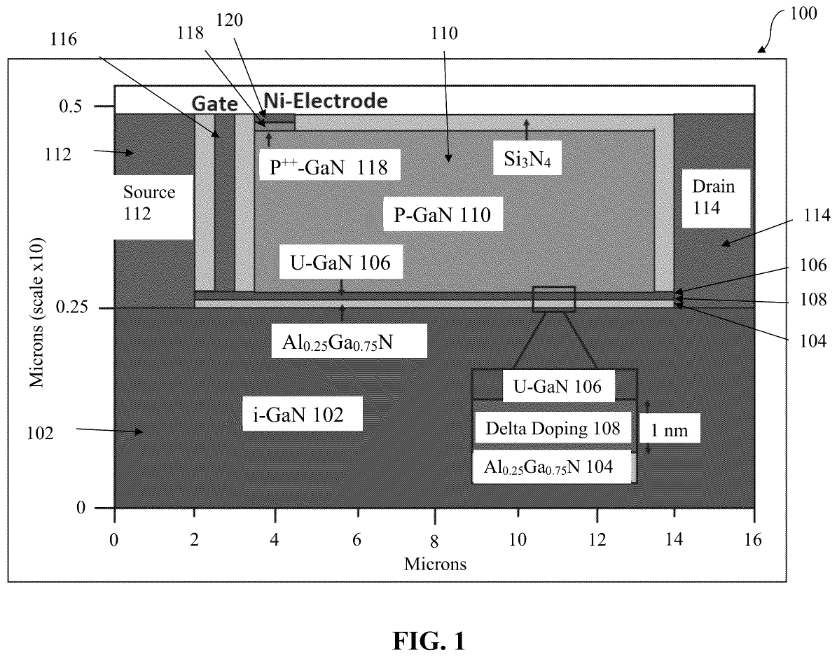

Embodiments may relate to a material structure. For example, as shown in FIG. 1, embodiments may relate to a material structure 100 of a super-heterojunction (SHJ) high electron mobility transistor (HEMT). FIG. 1 shows a cross sectional view of an exemplary material structure 100. The structure of a SHJ HEMT may include an “intrinsic” GaN layer 102 (e.g., i-GaN layer) specified as a substrate in the material region definition. As a non-limiting example, the i-GaN layer may be 250 nm thick. The i-GaN layer 102 may include a layer of undoped GaN on top of a substrate of differing material, for example, Sapphire.

Above the i-GaN layer 102 may be a layer of undoped Al_{0.25}Ga_{0.75}N 104 and a layer of unintentionally dopes U-GaN 106. As a non-limiting example, the Al_{0.25}Ga_{0.75}N layer 104 and the U-GaN layer 106 may each be 10 nm thick. Between the Al_{0.25}Ga_{0.75}N layer 104 and the U-GaN layer 106 may be a defined layer of delta doping 108. As a non-limiting example, the delta doping layer 108 may be 1 nm thick. The delta doping layer 108 may allow for increase in electron sheet density of a two-dimensional electron gas (2DEG), which may be formed at a lower Al_{0.25}Ga_{0.75}N layer 104 and i-GaN layer 102 interface. An exemplary thickness of 1 nm may be appropriate because delta doping is defined as an interfacial atomically thin highly doped region. The delta doping layer 108 may be defined at a Al_{0.25}Ga_{0.75}N layer 104 and U-GaN layer 106 interface because high doping concentrations may introduce impurity scattering which may decrease 2DEG mobility and because delta doping may introduce higher-energy surface states making thermal excitement of carriers from a P-GaN layer 110 and the U-Gan layer 106 over the Al_{0.25}Ga_{0.75}N layer 104 may be more energetically favorable.

A purpose of the U-GaN layer 106 may be to mitigate downward leakage of Mg-dopants into the Al_{0.25}Ga_{0.75}N layer 104 and 2DEG region. The structure of a SHJ HEMT may also include an ohmic source contact 112 and an ohmic drain contact 114. The ohmic source contact 112 and the ohmic drain contact 114 may lie on opposite sides of a channel making bottom contact to i-GaN layer 102 and making sidewall contact to the U-GaN layer 106/delta-doping layer 108/Al_{0.25}Ga_{0.75}N layer 104 structure. A Schottky gate 116 may contact the U-GaN layer 106 for electrostatic control of the channel.

The channel may have a natural SJH structure, with the P-GaN layer 110 having a P⁺⁺-GaN layer 118 and an ohmic Ni-electrode 120 on top of the P-GaN layer 110. As a non-limiting example, the P⁺⁺-GaN layer 118 may be 10 microns long by 200 nm thick, while the ohmic Ni-electrode 120 may be 1 micron long by 10 nm thick. A purpose of the Ni-electrode 120 may be to allow holes to deplete from the structure when biased. The Ni-electrode 120 may be electrically grounded with the ohmic source contact 112. A purpose of the P⁺⁺-GaN layer 118 may be to ensure the Ni-electrode 120 is an ohmic contact. In some embodiments, any remaining space in the SHJ structure may be filled with Si₃N₄.

Table 1 shows exemplary doping of each layer along with dimensions of each layer in an exemplary cross section and structure as shown in FIG. 1. The doping for the P-GaN layer 110 may be determined with regard to a doping balance SHJ theory with the delta-doping layer 108.

TABLE 1

| Region | Length (μm) | Thickness (μm) | Doping |
|---|---|---|---|
| P⁺⁺-GaN layer 118 | 1.000 | 0.010 | 1 × 10¹⁹/cm³ |
| P-Gan layer 110 | 10.000 | 0.200 | 3.75 × 10¹⁷/cm³ |
| U-GaN layer 106 | 12.000 | 0.010 | ~ |
| Delta-Doping layer | 12.000 | 0.001 | 7.5 × 10¹⁹/cm³ |
| 108 | | | |
| Al_{0.25}Ga_{0.75}N layer | 12.000 | 0.010 | ~ |
| 104 | | | |
| i-GaN layer 102 | 16.000 | 0.250 | ~ |
| Source 112/Drain 114 | 2.000 | 0.241 | ~ |
| Gate 116 | 0.500 | 0.221 | ~ |
| Nickel Electrode 120 | 1.000 | 0.010 | ~ |

It is understood that each layer and/or material shown in FIG. 1 may vary in length, thickness, size, and doping.

### EXAMPLES

The following examples are exemplary methods used to generate embodiments of the material structure 100 and test results from evaluating embodiments of the material structure 100 and methods of making and using the same.

The proposed GaN/AlGaN super-heterojunction (SHJ) high electron mobility transistor (HEMT) structure features may include 1) a SHJ structure with superjunction charge balancing between n-type and p-type doping to reduce peak electric fields at the drain-side of the transistor's gate contact. Reducing the peak electric fields at the drain-side may effectively increase breakdown voltage of the SHJ HEMT structure. Uniform redistribution of electric fields may occur across a channel region of the SHJ HEMT. The SHJ structure may functions as an improved field plate. The SHJ HEMT structure may further include 2) an ohmic Ni-electrode electrically grounded to the source electrode. The ohmic Ni-electrode may allow for improved static and/or dynamic switching performance behavior. In some embodiments, holes depleted from the p-type GaN may reenter through the Ni-Electrode. The SHJ HEMT structure may further include 3) a high n-type delta-doping layer which may increase 2-dimensional electron gas (2DEG) channel density. Use of a thick p-type GaN region may ensure that moderate-to-low doping is required for charge balancing with delta-doping. The SHJ HEMT structure may further include 4) class-A amplifier switching behavior up to 1 GHz with high output power due to high current densities and high breakdown fields.

In high-power GaN HEMT design, very high electric fields may occur. Peak electric fields greater than a critical electric field of a GaN may occur at the drain-side of the gate, thus limiting the maximum operating voltage of the amplifier. To avoid avalanche breakdown, Field Plates are typically used to reduce the peak electric field and redistribute the fields. Further reductions of peak electric fields may require an increased number of Field Plates, therefore resulting in an increase in fabrication time, cost, and complexity of HEMT devices. Field Plates may also introduce capacitive effects that degrade switching performance at high radio frequency (RF).

Embodiments of an SHJ structure and/or implementation may improve field control by replacing the need for Field Plates. Embodiments may reduce peak electric fields and may further improve redistribution of the field along the channel with a uniform distribution. Embodiments may also prove more economical and limit introduction of capacitive effects in SHJ HEMT devices.

A 2DEG layer of a SHJ HEMT device may have increased high-density due to incorporation of a delta-doping region at an upper GaN/AlGaN interface. The relatively thick p-type GaN region may have a reduced doping density and may be separated from the 2DEG layer by a GaN spacer region.

The ohmic Ni-electrode allows for improved switching performance (e.g., dynamic switching) by allowing holes to deplete and reenter the p-type GaN region when switching from off-to-on in AC transient.

Many industries, such as military radar, use traveling wave tube (TWT) devices, which may be replaced by high-power GaN technology if electric fields can be further controlled.

A lateral GaN FET, typically in the form of a high electron mobility transistor (HEMT), has been demonstrated with breakdown voltage (BV) below and into the kilovolt (kV) range, and upwards of 10 kV. However, dynamic switching of GaN FETs was only up to 1 kV off-state bias. This may be partly due to a limited BV of around 1 kV for a GaN-on-Si HEMT by the thickness of GaN achievable on a Si substrate. This is also because, although surface/buffer trapping may deplete the 2D electron gas (2DEG) between the gate and the drain leading to linear increase of BV with increasing gate-to-drain spacing L_{GD}, surface/buffer trapping may further cause severe degradation of dynamic on-resistance of a GaN FET making the device impractical to function as a switch.

A GaN-on-Sapphire super-heterojunction (SHJ) structure has been proposed and experimentally demonstrated, targeting a realization of high-voltage switches. In a charge-balanced SHJ structure, electrons and holes in the drift region are depleted, with a flattened E-field profile and a reduction of trapping. Implementation of the charge-balanced SHJ in Schottky barrier diodes (SHJ-SBD) have led to a record high measured BV of 12.5 kV and state-of-the-art dynamic switching performance with only a negligible 16.9% degradation of dynamic on-resistance at 3 kV.

As described, embodiments of the present subject matter provide experimental implementation of GaN SHJ transistors. First, a single-channel Schottky gate SHJ-FET device was fabricated. However, it was discovered that a realization of the SHJ design with transistors is more difficult than with diodes. This may be partly due to the following: (1) When a transistor is operating in the on-state, the reverse bias PN-junction of the SHJ region reduces output drain current I_{D} and increases drain-to-source on-resistance R_{DS(ON)} due to partial depletion of 2DEG by p-GaN. By contrast, the Schottky diode in forward conduction mode may forward bias the PN-junction, thus increasing forward current and reducing on-resistance. (2) The transistor must be designed to ensure electrical isolation between a gate and a p-type ohmic contact, while avoiding trapping in this region.

As described herein, double-channel SHJ-MOSFET devices are provided that may be designed and fabricated for enhanced performance compared to a single-channel SHJ-FET findings. Analysis of the single-channel SHJ-FET structure resulted in at least two improvements: (1) adoption of a double-channel structure may increase on-state I_{D} and reduce static R_{DS(ON)}; and (2) development of a process to eliminate surface trapping between the gate and p-GaN ohmic region for improved dynamic R_{DS(ON)}. Electrical measurements of the double-channel SHJ-MOSFET devices demonstrated reduced static on-resistance. For example, static on-resistance was found to be about 81.6 Ω·mm or 84.2 mΩ·cm², with controlled dynamic switching of up to 3 kV, and a blocking voltage of up to 10 kV.

### Single-Channel SHJ-FET Device Design & Fabrication

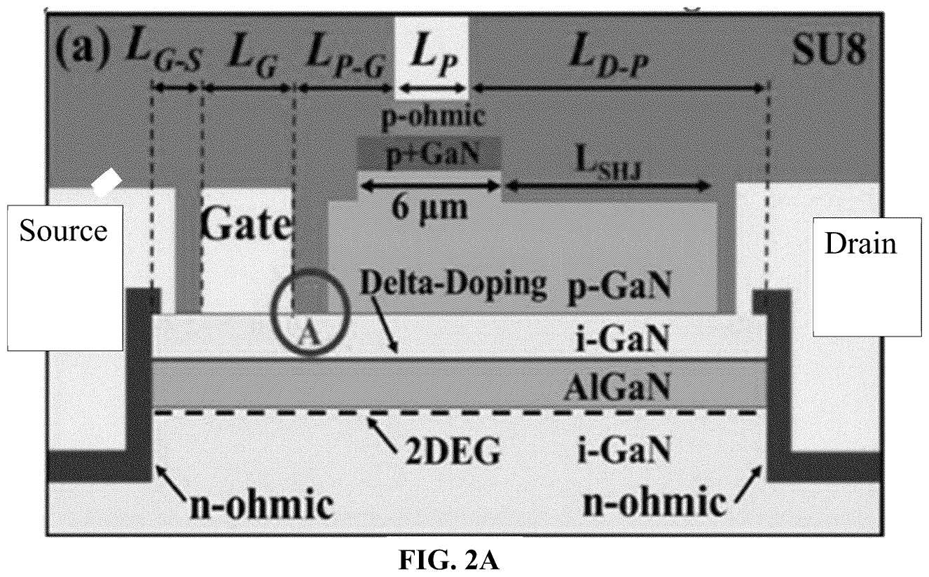

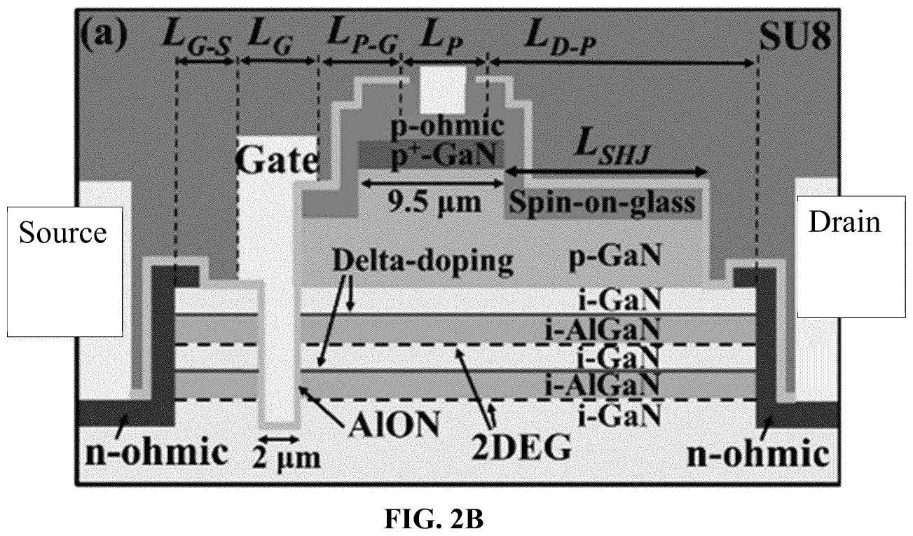

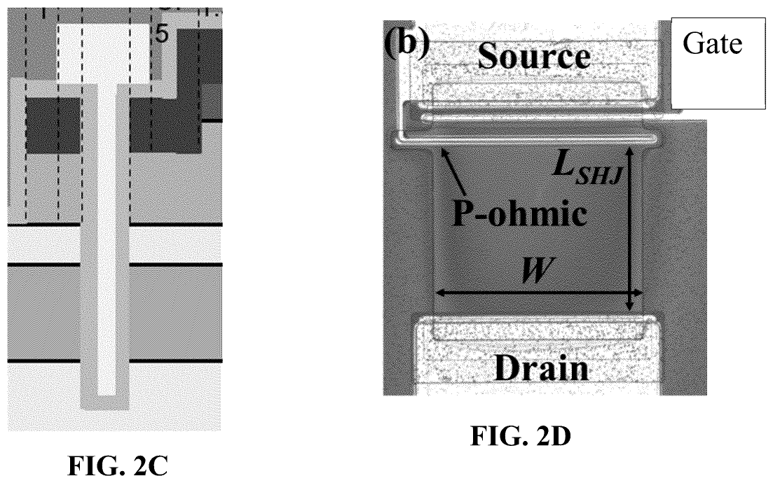

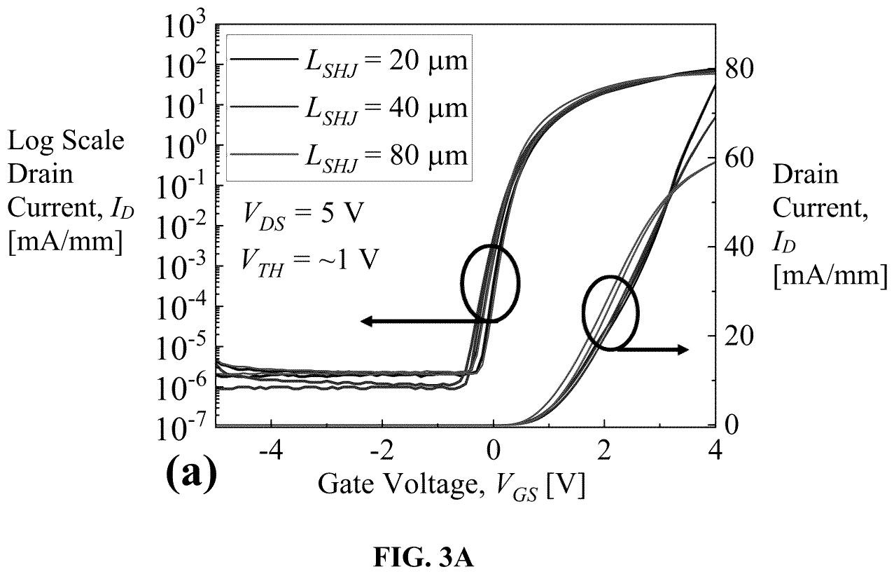

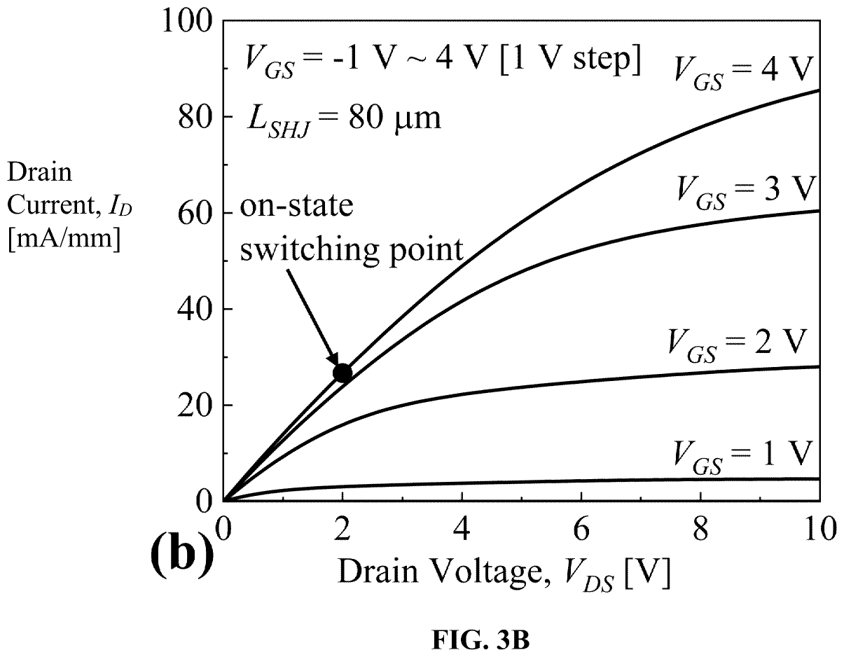

Referring to FIG. 2A, shown is a single-channel SHJ-FET with super-heterojunction length L_{SHJ}=100 μm. The single-channel SHJ-FET may be fabricated on a single-channel GaN on Sapphire epitaxial wafer grown via MOCVD. The structure, from the bottom-up, may include a Sapphire substrate, GaN buffer layer, an undoped GaN channel, an undoped Al_{0.25}Ga_{0.75}N layer, an undoped GaN spacer layer, a p-GaN layer, and finally, a p⁺-GaN layer. In non-limiting embodiments, the undoped GaN channel may be 300 nm, the undoped Al_{0.25}Ga_{0.75}N layer may be 10 nm, the undoped GaN spacer layer may be 70 nm, the p-GaN layer may be 250 nm, and the p⁺-GaN layer may have a 20 nm thickness. The p-GaN and p⁺-GaN layers may be Mg-doped, for example, 5×10¹⁷ cm⁻³ and 1.5×10²⁰ cm⁻³, respectively. The upper GaN/AlGaN interface may contain Si delta-doping with a sheet density of 7.5×10¹² cm⁻². The wafer has a 2DEG density of 3.33×10¹² cm⁻², electron mobility of 1189 cm²/Vs, and sheet resistance of 1593Ω/□, according to contactless Hall measurements. The high sheet resistance is a result of 2DEG partial depletion by the p-GaN.

Fabrication may begin with Mg activation annealing. GaN etching and device isolation etching may be performed using Cl₂/BCl₃-based inductively coupled plasma reactive ion etching (ICP-RIE) etching. The p⁺-GaN layer outside of the p-type ohmic contact may be etched away to prevent unwanted hole conduction through the p⁺-GaN layer. Isolation may be performed with Al⁺ implantation at a dosage of, for example, 1×10¹⁵ cm⁻² and an energy of 100 keV. Source and drain sidewall ohmic contacts, which may have a contact resistance of around 1.99 Ω·mm, may be formed by electron beam evaporation of 20/120 nm Ti/Al stack. The 10/40 nm Ni/Au p-type ohmic contact stack, which may have a contact resistance of around 1.41 kΩ·mm, may then be evaporated. Ohmic contact formations may be annealed concurrently. For example, the ohmic contact formations may be annealed at 550° C. in N₂. The 20/500 nm Ni/Au contact pads and Schottky gate metal may be evaporated and annealed at 300° C. in N₂. Fabrication may conclude with SU8 passivation.

### Single-Channel SHJ-FET Characterization Results & Discussion

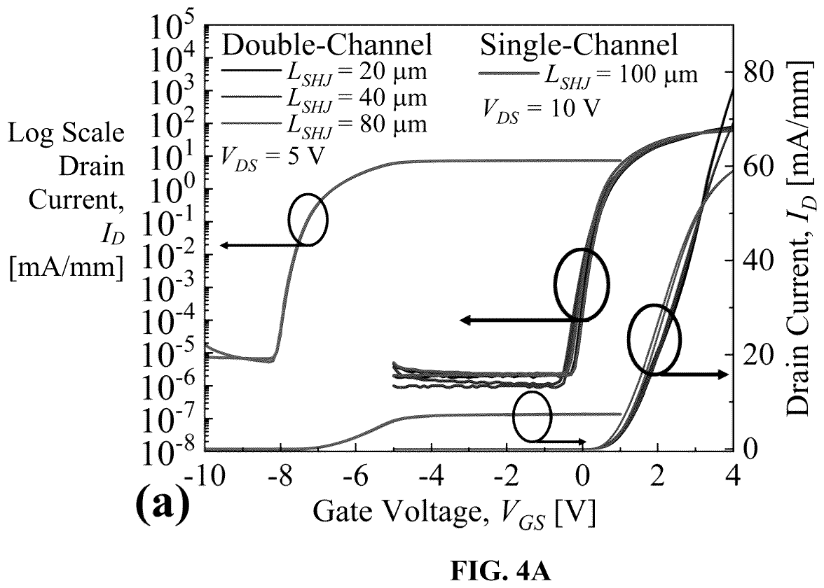

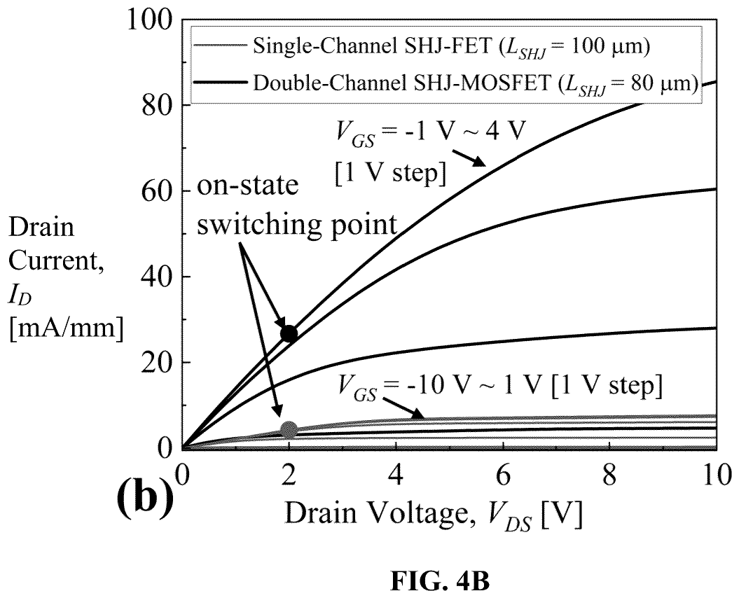

DC I-V and dynamic switching characteristics may be measured using Keysight's B1505A power device analyzer. In FIG. 4A, transfer I-V biased Vos from −10 V to 1 V and V_{DS}=10 Vis shown. For the single-channel SHJ-FET, a low I_{D} was found. The double sweep shows a threshold voltage of roughly −7 V with minimal hysteresis.

FIG. 4B shows output I-V for the single-channel SHJ-FET. Static and dynamic R_{DS(ON)} may be acquired at V_{DS}=2 V. A relatively large static R_{DS(ON)} of 466 Ω·mm may result. Normalized to device area, defined as the active area between the source and the drain contact trench sidewall, the static R_{DS(ON)} was found to be about 568.6 mΩ·cm². The large R_{DS(ON)} may be attributed to the reverse bias PN-junction of the SHJ region. When the device is in the on-state, the p-GaN may cause partial 2DEG depletion, increasing the R_{DS(ON)}. To further increase on-state I_{D} and reduce static R_{DS(ON)}, a double-channel structure may be utilized.

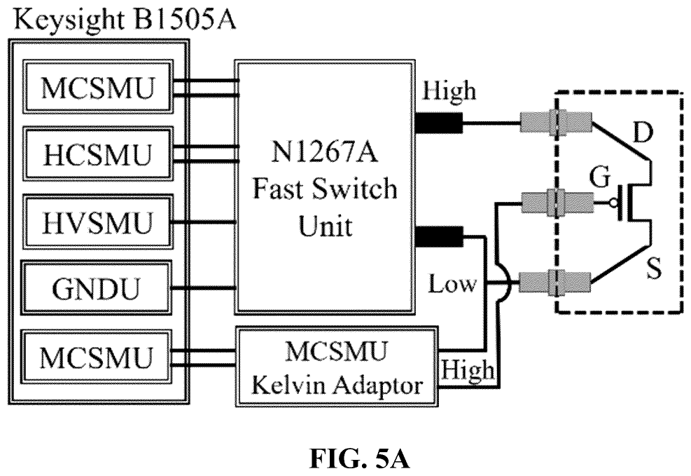

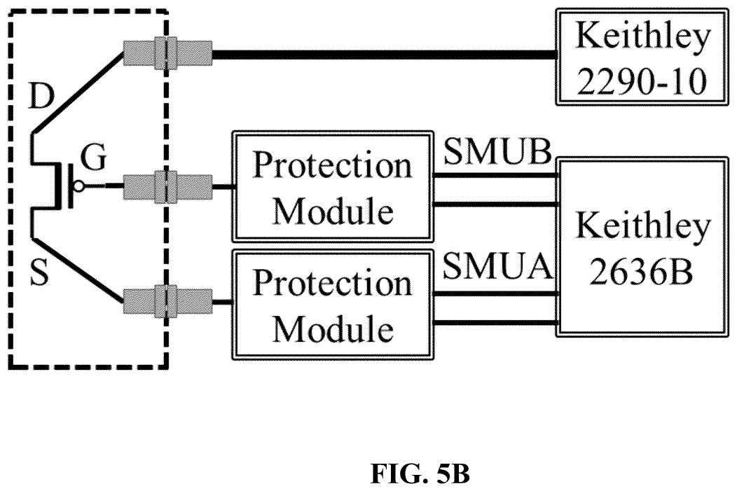

As shown in FIG. 5A, dynamic switching measurements may be performed using the Keysight N1267A fast switch unit. Performing dynamic switching measurements may require Keysight high current SMU, medium current SMU, high voltage SMU, and a ground unit to control the source and drain. A second medium current SMU may be used for controlling the gate. As an example, devices may be stressed for 1 second at an off-state V_{GS(OFF)}=−10 V and varied V_{DS (OFF)} stress from 1 V to 3 kV. The devices may then be switched from the off-state to the on-state, with on-state bias V_{GS(ON)}=1 V and V_{DS(ON)}=2 V, and held for 1 ms after switching. Dynamic R_{DS(ON)} may be calculated using measured I_{D} and VDs 1 ms after switching.

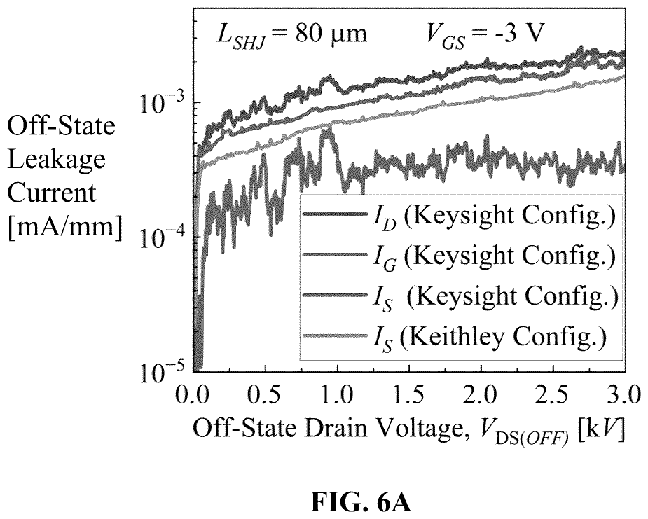

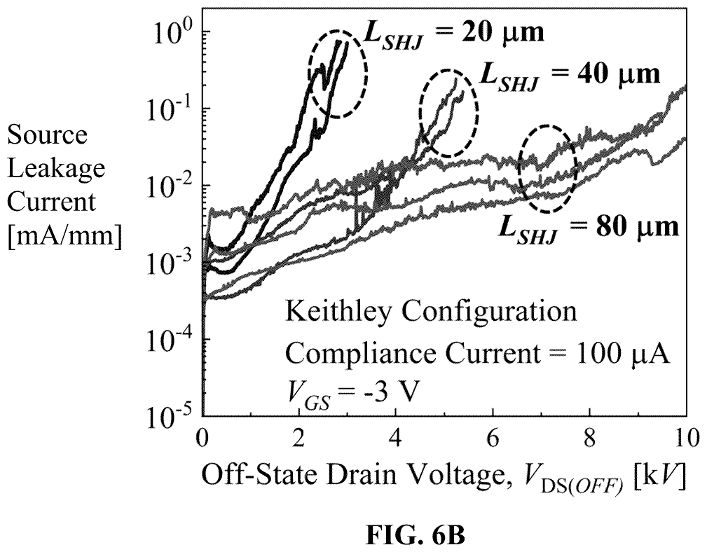

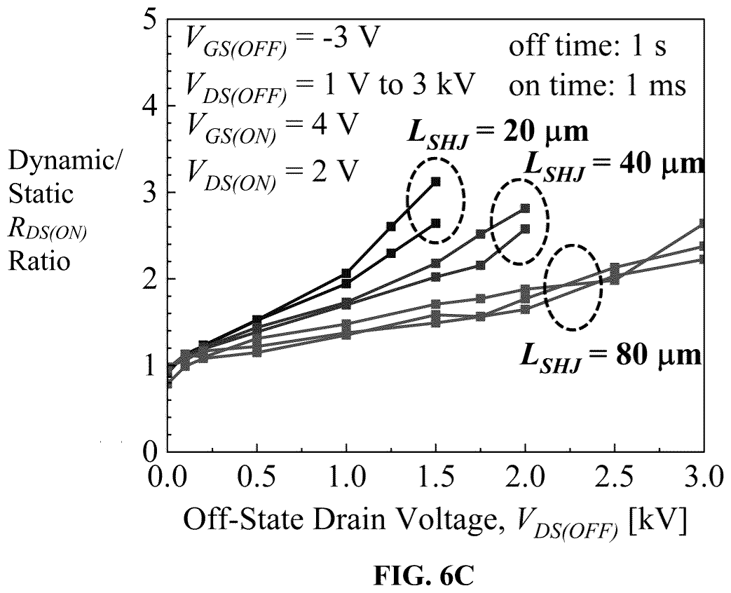

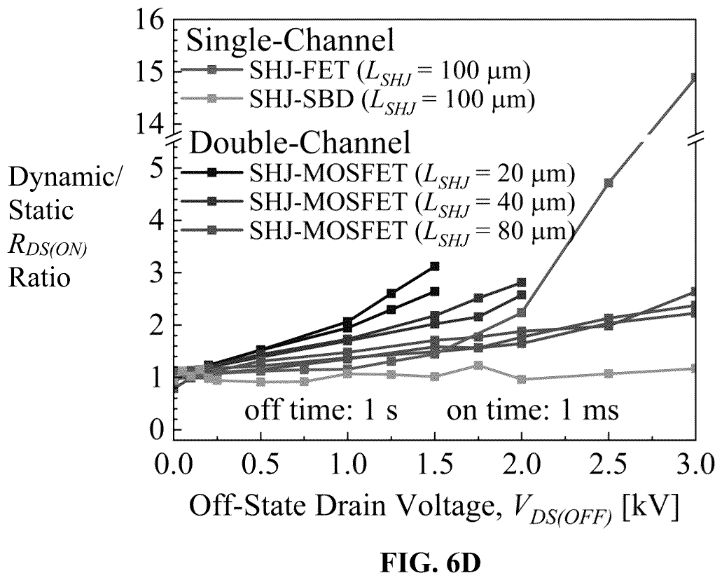

The ratio between the dynamic and static R_{DS(ON)} as shown in FIG. 6C displays a single-channel SHJ-FET with a negligeable 15.6% degradation after 1 kV off-state, 124% degradation after 2 kV, and total current collapse above 2 kV. While 2 kV switching is impressive, there is potential for 3 kV switching and beyond. One approach to improve the current collapse phenomenon is to meet the optimal charge-balance condition of the SHJ region via controlled charge-balance etching, reducing field-assisted trapping the SHJ region.

In some instances, an approach to mitigate current collapse may include eliminating possible electron trapping locations between the gate and the p-GaN ohmic region. It is hypothesized that the location, labelled “A” in FIG. 2A, may be the dominant reason for the poor switching characteristics. In a previous report and shown in FIG. 6C, the L_{SHJ}=100 μm single-channel SHJ-SBD demonstrated negligeable current collapse of 16.9% after 3 kV off-state. The SHJ-SBD and SHJ-FET may be fabricated together on a same sample with same processes and charge-balance conditions. The devices may be the same and/or similar in structure except for the existence of the possible trapping location between the drain-side gate edge and the p-GaN ohmic region of the SHJ-FET.

### Double-Channel SHJ-MOSFET Device Design & Fabrication

Shown in FIG. 2B is a cross-sectional schematic of an exemplary GaN double-channel SHJ-MOSFET device. A microscope image of an exemplary GaN double-channel SHJ-MOSFET device is shown in FIG. 2C, may be fabricated to improve performance over the single-channel SHJ-FET by: (1) implementing a double-channel wafer with reduced sheet resistance and a larger 2DEG density for reduced R_{DS(ON)} and increased on-state I_{D}; and by (2) eliminating the trapping location between the gate and p-GaN ohmic region to mitigate current collapse at larger off-state switching voltages.

A GaN double-channel SHJ-MOSFET device as shown in FIG. 2B may be fabricated on a double-channel GaN on Sapphire epitaxial wafer grown via MOCVD, similar to the single-channel epitaxial wafer. From the bottom-up, the structure may include a GaN buffer layer, an undoped GaN channel, an undoped Al_{0.25}Ga_{0.75}N layer, of an undoped GaN, an undoped Al_{0.25}Ga_{0.75}N layer, an undoped GaN spacer layer, a p-GaN layer, and a p⁺-GaN layer. In non-limiting embodiments, the undoped GaN channel may be 300 nm, the undoped Al_{0.25}Ga_{0.75}N layer may be 10 nm, the undoped GaN may be 40 nm, the undoped Al_{0.25}Ga_{0.75}N layer may be 10 nm, the undoped GaN spacer layer may be 70 nm, the p-GaN layer may be 250 nm, and the p⁺-GaN layer may be 20 nm. The p-GaN and p⁺-GaN layers may, in some examples, be Mg-doped 5×10¹⁷ cm⁻³ and 1.5×10²⁰ cm⁻³, respectively. Each of the two upper GaN/AlGaN interfaces may contain Si delta-doping with a sheet density of, for example, 7.5×10¹² cm⁻². The wafer may have a 2DEG density of 8.57×10¹² cm⁻², an electron mobility of 1562 cm²/Vs, and a sheet resistance of 467.8Ω/□. The GaN double-channel SHJ-MOSFET device may result in a significant increase in 2DEG density and reduction of sheet resistance compared to the single-channel wafer.

Fabrication of the GaN double-channel SHJ-MOSFET device may be similar to the single-channel process except for, for example, the gate structure. The gate structure may be formed by recessing across the double-channel layers, atomic layer deposition of 20 nm AlON as the gate dielectric, and evaporation of Ni/Au as the gate electrode. Spin-on-glass may be utilized for the recessed-gate trench etch to eliminate the i-GaN trapping location. The spin-on-glass may function as a protective layer for lithography and dry etch self-alignment. Source and drain sidewall ohmic contacts, formed by 20/120 nm Ti/Al, have contact resistance of 1.8 Ω·mm.

### Double-Channel SHJ-MOSFET Characterization Results & Discussion

FIG. 4A transfer I-V biased from V_{GS}=−5 V to 4 V at V_{DS}=5 V indicates increased L_{SHJ} may cause decreased on-state I_{D} at V_{GS}=4 V with no off-state I_{D} correlation identified. The double sweep indicated threshold voltage of ~1 V. FIG. 4B shows output I-V for a L_{SHJ}=80 μm SHJ-MOSFET. The averaged static R_{DS(ON)} values for L_{SHJ}=20 μm, 40 μm, and 80 μm designs are 51.7 Ω·mm (22.2 mΩ·cm²), 58.3 Ω·mm (36.7 mΩ·cm²), and 81.6 Ω·mm (84.2 mΩ·cm²), respectively.

When compared to the single-channel SHJ-FET, the double-channel L_{SHJ}=80 μm SHJ-MOSFET has larger on-state I_{D} and significantly smaller R_{DS(ON)} by 384.4 Ω·mm (82.5%) or 484.4 mΩ·cm² (85.6%).

Extracting the slope from the averaged R_{DS(ON)} as a function of L_{SHJ} provides a sheet resistance of 510.4Ω/□ for the SHJ region, 42.6Ω/□ larger than the measured wafer's sheet resistance. The reason for increased sheet resistance may be attributed to limited coupling between the top and bottom 2DEG channels. After electron transport underneath the recessed MOS gate, the AlGaN barrier between the two channels may prevent electron entry from the bottom channel into the top channel, compromising current conduction through the top channel. Double channel coupling may be improved by using a thinner GaN layer between the two AlGaN layers [23]. The resistance of the MOS channel, extracted from MOS channel sheet resistance of previous work, was 21.3 Ω·mm. The resistance component may account for, for example, 41.3%, 36.6%, and 26.2% of the total R_{DS(ON)} for L_{SHJ}=20 μm, 40 μm, and 80 μm designs, respectively. The region between the drain-side-edge of the gate trench and the drain-side-edge of the p⁺-GaN is 12 μm. This region may contribute little to voltage blocking while increasing R_{DS(ON)} by 11.9 Ω·mm and device length by 12 μm, especially noticeable for smaller L_{SHJ} designs.

The 80 μm SHJ-MOSFET design may compare favorably against previously reported 8-10 kV transistors in prior art. SHJ-MOSFETs may be limited to two channels because the vertical E-field at the PN-junction increases with increasing number of channels. The R_{DS(ON)} may be further improved by improving of MOS channel and the p-GaN ohmic region. This may, for example, entail shrinking dimensions between the source trench sidewall and drain-side-edge of the p⁺-GaN, and recessing only the top-channel with the gate terminating on the bottom AlGaN layer.

Shown in FIG. 5B is an off-state stress measurement configuration, where a 10 kV power supply (e.g., a Keithley 2290-10) provides the drain bias, and a Keithley 2636B dual channel SMU provides the source and gate bias, while measuring the source leakage current Is. FIG. 6B presents off-state I-V curves up to 10 kV using the Keithley configuration. The majority of L_{SHJ}=80 μm devices feature a BV greater than 10 kV. L_{SHJ}=20 μm and 40 μm SHJ-MOSFETs have an average BV of 2.93 kV and 5.32 kV, respectively, demonstrating a 119.5 V/μm scaling with L_{SHJ}.

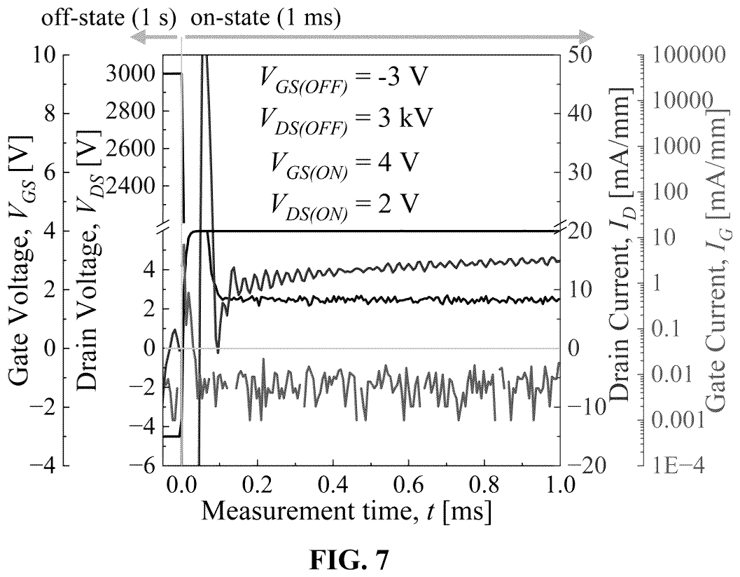

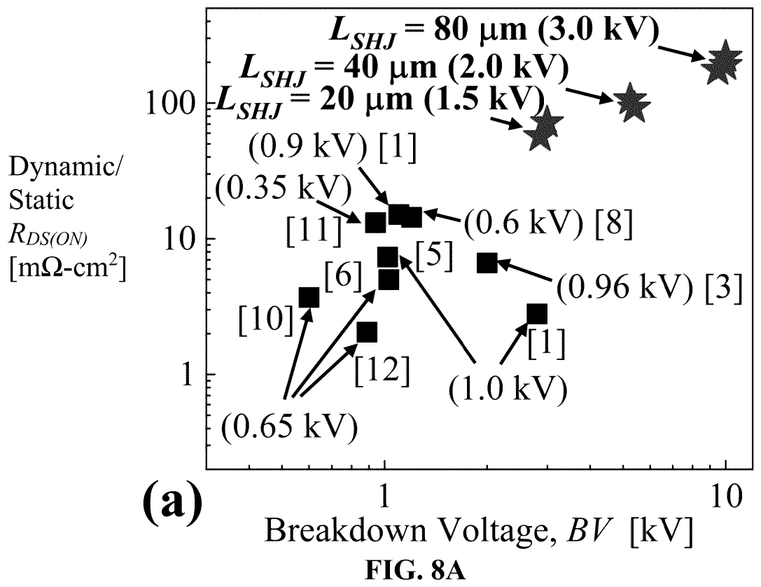

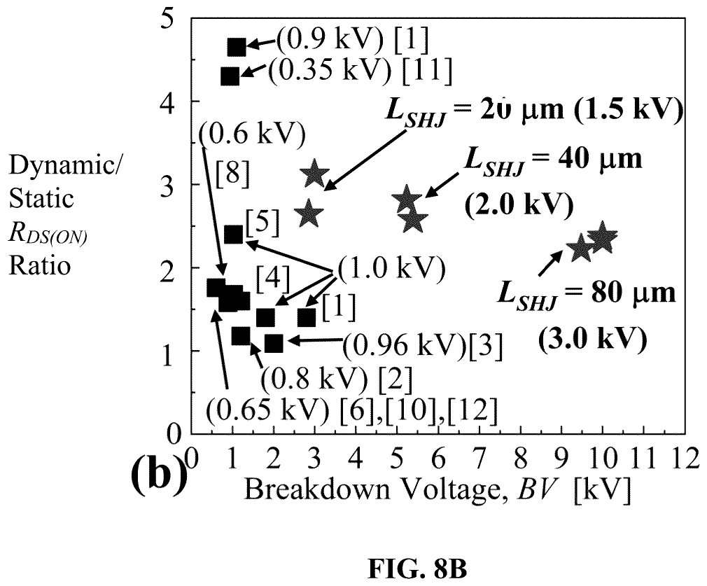

For dynamic switching measurements, FIG. 7 presents an example of switching waveforms measured on a L_{SHJ}=80 μm SHJ-MOSFET at 3 kV off-state. Gate and drain bias points applied in the on- and off-state are provided. FIG. 4 presents excellent switching up to 3 kV for L_{SHJ}=80 μm devices, boasting a minimum and average degradation of 123% and 131%, respectively, between the 3 devices. This represents the first report of GaN transistors dynamically switched at 3 kV, a factor of 3 times the previously highest reported switching voltage of 1 kV. The superior capability of the double-channel SHJ-MOSFETs, both in terms of blocking voltage and in terms of dynamic switching, is further exhibited in FIGS. 8A and 8B. FIG. 8A benchmarks the dynamic R_{DS(ON)} and FIG. 8B benchmarks the dynamic/static R_{DS(ON)} ratio of the double-channel SHJ-MOSFET devices reported in this letter against known state-of-the-art GaN transistors.

When comparing the 80 μm SHJ-MOSFET to the 100 μm single-channel SHJ-FET, by eliminating the trapping location between the gate and p-GaN ohmic region, dynamic R_{DS(ON)} decreased by 21% at 2 kV and decreased significantly by 84.5% at 3 kV. After switching from 2 kV off-state, the SHJ-FET and SHJ-MOSFET demonstrated degradation of 124% and 76.6%, respectively, and after 3 kV, degradation was 1389% and 131%, respectively.

The double-channel SHJ-MOSFET dynamic switching degradation can be further improved. At 3 kV, the L_{SHJ}=80 μm SHJ-MOSFETs demonstrated 91% more degradation than reported L_{SHJ}=100 μm single-channel SHJ-SBD, in FIG. 6D. The SHJ-MOSFET demonstrated degradation of 123%, while the SHJ-SBD demonstrated 16.9% degradation. After switching from a 2 kV off-state for L_{SHJ}=40 μm, SHJ-MOSFETs exhibit 94% larger dynamic on-resistance compared to SHJ-SBDs. The SHJ-MOSFET and SHJ-SBD demonstrated degradation of 170% and 39%, respectively. The worse dynamic on-resistance of the SHJ-MOSFETs is likely due to the increased field-assisted trapping due to suboptimal charge-balance of double-channel SHJ-MOSFETs.

### CONCLUSIONS

The experimental implementation of a GaN single-channel SHJ-FET was presented, but resulted in poor DC I-V and dynamic switching performance. Analysis of the device structure resulted in two key design changes: (1) utilization of double-channel structure for increased I_{D} and reduced R_{DS(ON)}; (2) Elimination of a dominant trapping location for current collapse mitigation. Experimental demonstration of the first GaN MOSFET capable of dynamic switching at 3 kV with mitigated current collapse and BV capability surpassing 10 kV was then presented. The GaN double-channel SHJ-MOSFET devices incorporated the key design improvements to enable superior experimental static and dynamic performance. While there is still room to reduce the static R_{DS(ON)} by optimizing the MOS channel and the p-GaN ohmic region, and to improve the dynamic switching performance by optimizing the SHJ charge balance region, strides towards high voltage GaN switching have been described herein.

It should be understood that the disclosure of a range of values is a disclosure of every numerical value within that range, including the end points. It should also be appreciated that some components, features, and/or configurations may be described in connection with only one particular embodiment, but these same components, features, and/or configurations can be applied or used with many other embodiments and should be considered applicable to the other embodiments, unless stated otherwise or unless such a component, feature, and/or configuration is technically impossible to use with the other embodiment. Thus, the components, features, and/or configurations of the various embodiments can be combined together in any manner and such combinations are expressly contemplated and disclosed by this statement.

It will be apparent to those skilled in the art that numerous modifications and variations of the described examples and embodiments are possible considering the above teachings of the disclosure. The disclosed examples and embodiments are presented for purposes of illustration only. Other alternate embodiments may include some or all of the features disclosed herein.

Therefore, it is the intent to cover all such modifications and alternate embodiments as may come within the true scope of this invention, which is to be given the full breadth thereof.

It should be understood that modifications to the embodiments disclosed herein can be made to meet a particular set of design criteria. Therefore, while certain exemplary embodiments of the compositions, materials, apparatuses, and methods of using and making the same disclosed herein have been discussed and illustrated, it is to be distinctly understood that the invention is not limited thereto but may be otherwise variously embodied and practiced within the scope of the following claims.

### REFERENCES

The following references are incorporated herein by reference in their entireties.
H. Handa et al., “High-speed switching and current-collapse-free operation by GaN gate injection transistors with thick GaN buffer on bulk GaN substrates,” in Technical Digest-International Electron Devices Meeting, IEDM, January 2017, pp. 10.3.1-10.3.4. doi: 10.1109/IEDM.2016.7838387.
Y. F. Wu, J. Gritters, L. Shen, R. P. Smith, and B. Swenson, “KV-class GaN-on-Si HEMTs enabling 99% efficiency converter at 800 v and 100 kHz,” IEEE Trans Power Electron, vol. 29, no. 6, pp. 2634-2637 June 2014, doi: 10.1109/TPEL.2013.2284248.
G. Gupta et al., “1200V GaN Switches on Sapphire Substrate,” in Proceedings of the International Symposium on Power Semiconductor Devices and ICs, 2022, vol. 2022-May, pp. 349-352. doi: 10.1109/ISPSD49238.2022.9813640.
T. Kikkawa et al., “600 v JEDEC-qualified highly reliable GaN HEMTs on Si substrates,” in Technical Digest—International Electron Devices Meeting, IEDM, February 2015, vol. 2015-February, no. February, pp. 2.6.1-2.6.4. doi: 10.1109/IEDM.2014.7046968.
R. Hao et al., “Breakdown Enhancement and Current Collapse Suppression by High-Resistivity GaN Cap Layer in Normally-Off AlGaN/GaN HEMTs,” IEEE Electron Device Letters, vol. 38, no. 11, pp. 1567-1570 November 2017, doi: 10.1109/LED.2017.2749678.
G. Tang et al., “Dynamic RON of GaN-on-Si lateral power devices with a floating substrate termination,” IEEE Electron Device Letters, vol. 38, no. 7, pp. 937-940, July 2017, doi: 10.1109/LED.2017.2707529.
S. W. Han, J. G. Lee, C. H. Cho, and H. Y. Cha, “Dynamic on-resistance of normally-off recessed AlGaN/GaN-on-Si metal-oxide-semiconductor heterojunction field-effect transistor,” Applied Physics Express, vol. 7, no. 11, p. 111002, November 2014, doi: 10.7567/APEX.7.111002.
R. Chu et al., “1200-V normally off GaN-on-Si field-effect transistors with low dynamic on-resistance,” IEEE Electron Device Letters, vol. 32, no. 5, pp. 632-634, May 2011, doi: 10.1109/LED.2011.2118190.
N. Q. Zhang, B. Moran, S. P. DenBaars, U. K. Mishra, X. W. Wang, and T. P. Ma, “Effects of surface traps on breakdown voltage and switching speed of GaN power switching HEMTs,” Technical Digest-International Electron Devices Meeting, pp. 589-592, 2001, doi: 10.1109/IEDM.2001.979575.
Z. Tang et al., “600-V normally off SiNx/AlGaN/GaN MIS-HEMT with large gate swing and low current collapse,” IEEE Electron Device Letters, vol. 34, no. 11, pp. 1373-1375, 2013, doi: 10.1109/LED.2013.2279846.
W. Saito et al., “A 120-W boost converter operation using a high-voltage GaN-HEMT,” IEEE Electron Device Letters, vol. 29, no. 1, pp. 8-10, January 2008, doi: 10.1109/LED.2007.910796.
Z. Tang, S. Huang, Q. Jiang, S. Liu, C. Liu, and K. J. Chen, “High-voltage (600-V) low-leakage low-current-collapse AlGaN/GaN HEMTs with AlN/SiNx passivation,” IEEE Electron Device Letters, vol. 34, no. 3, pp. 366-368, 2013, doi: 10.1109/LED.2012.2236638.
M. Xiao et al., “Multi-Channel Monolithic-Cascode HEMT (MC2-HEMT): A New GaN Power Switch up to 10 kV,” in Technical Digest—International Electron Devices Meeting, IEDM, 2021, vol. 2021-December, pp. 5.5.1-5.5.4. doi: 10.1109/IEDM19574.2021.9720714.
R. Vetury, N. Q. Zhang, S. Keller, and U. K. Misha, “The impact of surface states on the DC and RF characteristics of AlGaN/GaN HFETs,” IEEE Trans Electron Devices, vol. 48, no. 3, pp. 560-566, 2001, doi: 10.1109/16.906451.
S. W. Han and R. Chu, “Chapter 5-III-Nitride lateral transistor power switch,” in Semiconductors and Semimetals, vol. 102, Academic Press Inc., 2019, pp. 185-218. doi: 10.1016/bs.semsem.2019.08.007.
S. W. Han, J. Song, and R. Chu, “Design of GaN/AlGaN/GaN Super-Heterojunction Schottky Diode,” IEEE Trans Electron Devices, vol. 67, no. 1, pp. 69-74, January 2020, doi: 10.1109/TED.2019.2953843.
A. Nakajima, K. Adachi, M. Shimizu, and H. Okumura, “Improvement of unipolar power device performance using a polarization junction,” Appl Phys Lett, vol. 89, no. 19, 2006, doi: 10.1063/1.2372758.
S. W. Han et al., “Experimental Demonstration of Charge-Balanced GaN Super-Heterojunction Schottky Barrier Diode Capable of 2.8 kV Switching,” IEEE Electron Device Letters, vol. 41, no. 12, pp. 1758-1761 December 2020, doi: 10.1109/LED.2020.3029619.
A. Nakajima, Y. Sumida, M. H. Dhyani, H. Kawai, and E. M. Narayanan, “GaN-based super heterojunction field effect transistors using the polarization junction concept,” IEEE Electron Device Letters, vol. 32, no. 4, pp. 542-544, April 2011, doi: 10.1109/LED.2011.2105242.
S. W. Han et al., “12.5 kV GaN Super-Heterojunction Schottky Barrier Diodes,” IEEE Trans Electron Devices, vol. 68, no. 11, pp. 5736-5741 November 2021, doi: 10.1109/TED.2021.3111543.
J. T. Kemmerling et al., “Impact of Charge Balance on Static and Dynamic Characteristics of GaN Super-Heterojunction Schottky Barrier Diodes,” IEEE Electron Device Letters, vol. 43, no. 5, pp. 701-704, May 2022, doi: 10.1109/LED.2022.3163236.
J. Song, S. W. Han, H. Luo, J. Rumsey, J. H. Leach, and R. Chu, “Study of interface trap density of AlOxNy/GaN MOS structures,” Appl Phys Lett, vol. 119, no. 12, September 2021, doi: 10.1063/5.0062581.
J. Wei, J. Lei, X. Tang, B. Li, S. Liu, and K. J. Chen, “Channel-to-Channel Coupling in Normally-Off GaN Double-Channel MOS-HEMT,” IEEE Electron Device Letters, vol. 39, no. 1, pp. 59-62, January 2018, doi: 10.1109/LED.2017.2771354.
J. W. Palmour et al., “Silicon carbide power MOSFETs: Breakthrough performance from 900 v up to 15 kV,” in Proceedings of the International Symposium on Power Semiconductor Devices and ICs, 2014, pp. 79-82. doi: 10.1109/ISPSD.2014.6855980.
J. B. Casady et al., “New Generation 10 kV SiC Power MOSFET and Diodes for Industrial Applications,” in PCIM Europe 2015; International Exhibition and Conference for Power Electronics, Intelligent Motion, Renewable Energy and Energy Management, 2015, pp. 96-103.
Y. Uemoto et al., “8300V blocking voltage AlGaN/GaN power HFET with thick poly-AlN passivation,” in Technical Digest—International Electron Devices Meeting, IEDM, 2007, pp. 861-864. doi: 10.1109/IEDM.2007.4419085.

1. A super-heterojunction structure, comprising:
a p-ohmic layer, wherein the p-ohmic layer is electrically grounded to a source electrode, and wherein the source electrode is electrically grounded to at least one two-dimensional electron gas (2DEG) channel.

2. The super-heterojunction structure of claim 1, wherein the at least one 2DEG channel comprises:
at least one n-type modulation doped layer; and
at least one p-type layer.

3. The super-heterojunction structure of claim 1, wherein the p-ohmic layer comprises a p-ohmic contact metal.

4. The super-heterojunction structure of claim 2, wherein:
the n-type modulation doped layer is formed by any one or combination of:
n-type barrier layer doping; and
n-type δ-doping in the barrier layer; and n-type doping at an interface between the barrier layer and the at least one p-type layer; and
n-type δ-doping at an interface between the barrier layer and the at least one p-type layer.

5. The super-heterojunction structure of claim 2, wherein:
the n-type modulation doped layer is adjacent to the p-type layer to generate a charge balanced super-heterojunction region;
the at least one p-type layer comprises at least two p-type layers;
a first p-type layer comprises, GaN;
a second p-type layer comprises, AlGaN.

6. The super-heterojunction structure of claim 2, wherein:
a p-type dopant for the p-type layer comprises any one or combination of Mg, Li, Na, K, Be, Zn Ca, and Be.

7. The super-heterojunction structure of claim 1, further comprising:
at least one second 2DEG channel.

8. The super-heterojunction structure of claim 1, comprising:
a plurality of 2DEG channels of claim 1.

9.-34. (canceled)

35. A super-heterojunction structure, comprising:
a p-ohmic contact designed to only contact a p+ layer.

36. The super-heterojunction structure of claim 35, wherein the p-ohmic contact is electrically shorted with a source contact.

37. The super-heterojunction structure of claim 35, further comprising a continuous gate trench sidewall on the p-ohmic contact side of a gate trench of a gate contact,
wherein the p-ohmic contact is electrically isolated from the gate contact,
wherein the gate contact has a symmetric or asymmetric structure and the gate contact design reduces trapping between the gate contact and the p-ohmic contact.

38.-41. (canceled)

42. The super-heterojunction structure of claim 35, wherein a termination of the p-ohmic contact is at an edge of a transistor isolation side-wall for electric-field termination.

43. The super-heterojunction structure of claim 35, wherein a termination of the p-ohmic contact overhangs an edge of a transistor isolation side-wall for electric-field termination.

44. The super-heterojunction of claim 35, wherein the termination of the p-ohmic contact comprises an extension of a device active region outside a rectangular isolation sidewall.

45. The super-heterojunction structure of claim 35, wherein the termination of the p-ohmic contact comprises no extension of a device active region outside a rectangular isolation sidewall.

46. The super-heterojunction structure of claim 35, wherein the termination of the p-ohmic contact comprises a p+-type layer unetched at a transistor isolation side-wall.

47. The super-heterojunction structure of claim 35, wherein the termination of the p-ohmic contact comprises a p+-type layer etched at a transistor isolation side-wall.

48. The super-heterojunction structure of claim 35, wherein a metal connection between the source contact and the p-ohmic contact is within a surface area of the p-ohmic contact and the p+-type layer.

49. The super-heterojunction structure of claim 35, wherein a metal connection between the source contact and the p-ohmic contact is outside a surface area of the p-ohmic contact and the p+-type layer.

50. The super-heterojunction structure of claim 35, further comprising an etch opening of the spin-on-glass (SiO2) or other protective layer; and
an etch opening of a gate dielectric layer for a connection of metal to the p-ohmic contact,
wherein the connection of metal is limited to within a surface area of the p-ohmic contact and the p+-type layer.
